(19) United States
(12) Patent Application Publication
(10) Pub. No.: US 2026/0056258 A1
(43) Pub. Date: Feb. 26, 2026

(54) BATTERY DEPLETION MONITOR

(71) Applicant: Medtronic, Inc., Minneapolis, MN (US)

(72) Inventors: Michael B. Terry, Seattle, WA (US); Jonathan P. Roberts, Coon Rapids, MN (US); Joel A. Anderson, Brooklyn Park, MN (US)

(21) Appl. No.: 18/997,605

(22) PCT Filed: Jul. 6, 2023
(86) PCT No.: PCT/IB2023/057003

§ 371 Date: Jan. 22, 2025

Related U.S. Application Data
(60) Provisional application No. 63/369,577, filed on Jul. 27, 2022.

(51) Int. Cl. G01R 31/388; G01R 1/20; G01R 19/165; G01R 31/36; G01R 31/371; G08B 21/18

(52) U.S. Cl. CPC G01R 31/388; G01R 1/203; G01R 19/16542; G01R 31/3646; G01R 31/371; G08B 21/182

(57) ABSTRACT

Systems, circuit arrangements, and circuit operation that determine the state of charge of a battery used to provide power to an electrically powered device. The example circuit arrangement of this disclosure may include a selectable sense resistor circuit, a voltage-controlled oscillator (VCO) with a programmable gain preamplifier, an integrator, and a comparator configured to sample the sense resistor measurement and determine an amount of charge from the battery per unit time. The circuit operation may also include slow chop technique to cancel residual input referred offset, where “slow” refers to a chop period that is much longer than the clock period and sample period. By counting the total charge amount used by the electrically powered device and knowing the initial battery charge level at the beginning of life for the battery, the system of this disclosure may determine the state of charge of the battery.

This application claims the benefit of U.S. Provisional Patent Application Ser. No. 63/369,577, filed Jul. 27, 2022, the entire content of which is incorporated herein by reference.

### TECHNICAL FIELD

The disclosure relates to battery management for electrically powered devices, including implantable medical devices.

### BACKGROUND

Small devices, such as implantable medical devices, may use a battery to provide power to perform the device functions, which may include monitoring the patient using sensing circuitry and, in some examples, managing a condition of the patient by delivering therapy. Some examples of therapy delivery may include drug delivery and electrical stimulation therapy directed at target tissue of the patient. Some examples of batteries may be rechargeable while other examples may be non-rechargeable, referred to as primary batteries, and may be implemented with a variety of different battery chemistries, such as lithium-ion. Determining how much electrical energy remains in the battery may be useful information to let a patient, or caregiver, know when to recharge the battery, or for devices with a primary battery, to replace the device before the battery end of life.

### SUMMARY

In general, the disclosure describes systems, circuit arrangements, and circuit operation to determine the state of charge of a battery that provides power to an electrically powered device. In some examples, the electrically powered device is a medical device, which may include an implantable medical device (IMD). In some examples the state of charge (SoC) of a battery, which indicates how much electrical energy remains in the battery, e.g., in amp-hours (Ahr), may also be referred to as depth of discharge (DoD), in this disclosure.

For electrically powered devices that run at a fairly constant power state throughout the device life, processing circuitry associated with the device may estimate the SoC of the battery based on, for example, an average current draw over the time the device is in operation. However, for devices that include large variations in power use, such as devices that periodically charge and discharge large capacitors, e.g., to provide defibrillation therapy, keeping accurate track of total battery depletion may be challenging. Some examples of battery depletion monitoring for more complex devices may themselves be complex, subject to errors, and may draw enough power from the battery to impact device longevity, especially for smaller, low power devices, with smaller battery capacity.

The circuit arrangement of this disclosure may include a selectable sense resistor circuit configured to compensate for changes in resistance caused by changes in temperature, e.g., the temperature coefficient of resistance. The circuit arrangement may also include a voltage-controlled oscillator (VCO) with a programmable gain preamplifier, an integrator, and a comparator configured to sample the sense resistor measurement and determine an amount of charge from the battery per unit time. The circuit operation may also include slow chop technique to cancel residual input referred offset, where “slow” refers to a chop period that is much longer than the clock period and sample period. The average of each half period of the total chop period cancels the input offset. By counting the total charge amount used by the electrically powered device and knowing the initial battery charge level at the beginning of life for the battery, the system of this disclosure may determine the state of charge of the battery.

In one example, this disclosure describes a circuit configured to measure an amount of charge consumed over a duration of time comprising a sense resistor comprising a first terminal and a second terminal, wherein the first terminal connects to a power supply terminal and the second terminal connects to a load, and wherein the sense resistor is configured to develop a sense voltage proportional to an instantaneous load current, wherein the instantaneous load current is a magnitude of current consumed by the load; switched capacitor preamplifier circuitry comprising an amplifier, input switches, and input capacitors, wherein the switched capacitor preamplifier circuitry is configured to operate in a plurality of modes comprising a clear mode, wherein when operating in the clear mode, the amplifier is configured as a differential amplifier and the input switches connect the input capacitors to the second terminal of the sense resistor; integrator circuitry configured to receive a sampled voltage indicative of the sense voltage from the switched capacitor preamplifier circuitry and, while in an integrate mode, integrate the sampled voltage and output the integrated sampled voltage; and a comparator configured to: receive the integrated sampled voltage from the integrator circuitry; and compare the received integrated sampled voltage to a threshold voltage; output an indication of the amount of charge consumed by the load, based on the comparison.

In another example, this disclosure describes a system comprising a circuit configured to measure an amount of charge consumed over a duration of time, the circuit comprising: a sense resistor comprising a first terminal and second terminal, wherein the first terminal connects to a power supply terminal and the second terminal connects to a load, and wherein the sense resistor is configured to develop a sense voltage proportional to an instantaneous load current and the instantaneous load current is a magnitude of current consumed by the load; switched capacitor preamplifier circuitry comprising an amplifier, input switches, and input capacitors, the switched capacitor preamplifier circuitry configured to operate in a plurality of modes comprising a clear mode, wherein when operating in the clear mode, the amplifier is configured as a differential amplifier and the input switches connect the input capacitors to the second terminal of the sense resistor; integrator circuitry configured to receive the sampled voltage indicative of the sense voltage from the switched capacitor preamplifier circuitry, and while in integrate mode, integrate the sampled voltage and output the integrated sampled voltage; a comparator configured to: receive the integrated sampled voltage from the integrator circuitry; and compare the received integrated sampled voltage to a threshold voltage; output an indication of a fixed amount of charge consumed by the load, based on the comparison; and digital control circuitry configured to output control signals and control operation of the switched capacitor preamplifier circuitry, the integrator circuitry and input switches by means of the control signals.

In another example, this disclosure describes a method for measuring an amount of electrical energy consumed over a duration of time comprising: controlling, by digital control circuitry, a switched capacitor switched capacitor preamplifier circuit to measure a sense voltage across a sense resistor, wherein the sense voltage is proportional to an instantaneous load current, wherein the switched capacitor preamplifier circuit samples the sense voltage and outputs the sampled sense voltage, wherein the instantaneous load current is a magnitude of current consumed by a load, wherein the sense resistor comprises a first terminal and second terminal, wherein the first terminal connects to a power supply terminal, wherein the second terminal connects to a load, and wherein the switched capacitor preamplifier circuit comprises: a first amplifier, switches, input capacitors, and wherein controlling the switched capacitor preamplifier circuit comprises operating, by the digital control circuitry, the switched capacitor preamplifier circuit in a plurality of modes; configuring, by the digital control circuitry, the switched capacitor preamplifier circuit to operate in a clear mode, wherein the clear mode comprises: configuring, by the digital control circuitry, the first amplifier as a differential amplifier, and controlling the switches to connect the input capacitors to the second terminal of the sense resistor; controlling, by the digital control circuitry, an integrator circuit to: receive the sampled voltage indicative of the sense voltage from the switched capacitor preamplifier circuit; operate in an integrate mode to integrate the sampled voltage, and output the integrated sampled voltage; receiving, by the digital control circuitry and from a comparator operatively coupled to the integrator circuit, an indication of the amount of charge consumed by the load.

The details of one or more examples of the disclosure are set forth in the accompanying drawings and the description below. Other features, objects, and advantages of the disclosure will be apparent from the description and drawings, and from the claims.

### BRIEF DESCRIPTION OF DRAWINGS

FIG. 1 is a block diagram illustrating an example overview of an example circuit configured to determine an amount of charge per unit time consumed from a power source.

FIG. 2A is a schematic diagram illustrating an example circuit configured to determine an amount of charge per unit time, including a dual path arrangement.

FIG. 2B is a schematic diagram illustrating an example implementation of the clocked comparator circuit of this disclosure.

FIG. 3A is a timing chart illustrating an example operation of a Coulomb counter circuit.

FIGS. 3B and 3C are schematic diagrams illustrating the different phases or modes of operation for the charge sensing circuit of this disclosure according to the clock signal timing.

FIGS. 4A and 4B are timing diagrams illustrating an example operation of components of a Coulomb counter circuit according to one or more techniques of this disclosure.

FIG. 5A is a schematic diagram illustrating an example implementation of amplifier components for the preamplifier of the charge counting circuitry according to one or more techniques of this disclosure.

FIG. 5B is a schematic diagram illustrating an example implementation of amplifier components for the integrator circuit of the charge sensing circuitry according to one or more techniques of this disclosure.

FIG. 6 is a schematic diagram illustrating an example switched capacitor preamplifier circuit according to one or more techniques of this disclosure.

FIG. 7 is a schematic diagram illustrating an example anti-aliasing low pass filter and chop multiplexor according to one or more techniques of this disclosure.

FIG. 8 is a functional block diagram illustrating an example configuration of an implantable medical device including an example Coulomb counter circuit of this disclosure.

FIG. 9 is a flow diagram illustrating an example operation of the charge sense circuitry of this disclosure.

### DETAILED DESCRIPTION

In general, the disclosure describes systems, circuit arrangements, and circuit operation to determine the state of charge of a battery that provides power to an electrically powered device. In some examples, the electrically powered device is a medical device, which may include an implantable medical device (IMD), that incorporates the systems, circuit arrangements, and circuit operations described herein. In some examples the state of charge (SoC) of a battery, which indicates how much electrical energy remains in the battery, e.g., in amp-hours (Ahr), may also be referred to as depth of discharge (DoD), in this disclosure.

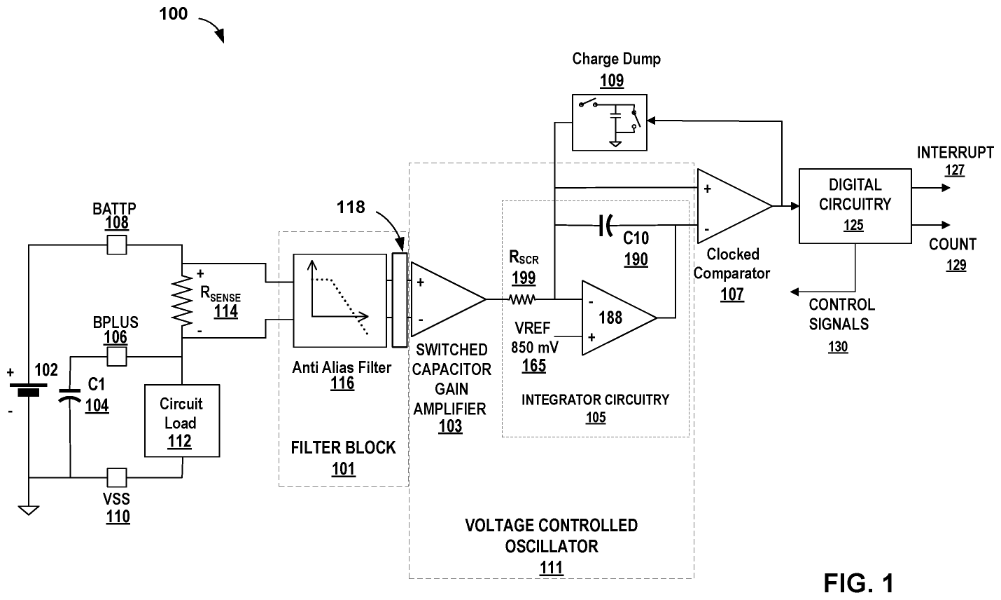

FIG. 1 is a block diagram illustrating an overview of an example circuit configured to determine an amount of charge per unit time consumed from a power source. In the example of FIG. 1, the power source is battery 102, which supplies power to a load, circuit load 112. In the example of system 100 of FIG. 1, circuit load 112 connects between Vss 110, connected to the battery negative terminal and BPLUS 105 connected to the battery positive terminal. An additional terminal, BPLUS 106 connects to circuit load 112, and through C1 104 to Vss 110.

The charge sensing circuit includes a sense resistor, Rsense 114, with the first terminal connect to the power supply terminal, BATTP 108, and the second terminal of Rsense 114 connected to circuit load 112. Rsense 114 may sense voltage proportional to an instantaneous load current, e.g., the magnitude of current consumed by circuit load 112.

As an overview, the circuit arrangement of this disclosure may include a selectable sense resistor circuit, Rsense 114 configured to compensate for changes in resistance caused by changes in temperature, e.g., the temperature coefficient of resistance. The sense resistor circuit has a selectable impedance to operate in a variety of applications based on the battery capacity, operating current and other factors for the application. The circuit further includes an input filter 116 configured to suppress aliasing, yet capture the total energy sensed at the input. The circuit arrangement may also include a voltage-controlled oscillator (VCO) 111 with a programmable gain preamplifier 103, an integrator 105 connected to a comparator 107 and a charge dump circuit 109.

In some examples, the preamplifier and the integrator have dual signal paths with opposite clock phasing, which may provide bilinear sampling of the filtered input signal from the sense resistor. Bilinear sampling provides a sampling rate that is double the clock rate. For each signal path, the preamplifier 103 provides an amplified, sampled value to the integrator 105. The integrator output voltage decrements to a reference voltage 165 at each sample time step and trips comparator 107 when the integrator output voltage passes reference voltage 165 generating a count for an amount of charge from the battery (e.g., a micro-Coulomb—μC). The circuit operation may also include slow chop technique to cancel residual input referred offset, where “slow” refers to a chop period that is much longer than the clock period and sample period. In some examples the slow chop period may be 100, 1000, 100,000 or more times the sampling period. In some examples, a chopping multiplexor (mux) 118 receives the output of input filter 116 and feeds VCO block 111 of the circuit so that VCO block 111 samples the filtered input signal (VSENSE) with a positive gain, e.g., +1, for half of the chop period. For the other half period, VCO block 111 takes multiple samples with an inverted gain, e.g., −1 or 180 degrees. The average of the two half periods cancels the input offset.

In the example of system 100, the sense voltage across Rsense 114 is amplified by a preamplifier after passing through anti-aliasing filter 116. In some examples, anti-aliasing filter 116 is a low-pass filter that may be implemented as a fully differential structure. In one example implementation, the low pass cutoff frequency may be set to approximately 50 Hz, which provides more than −25 dB of cutoff rejection at a sampling rate of 1024 Hz and approximately −20 dB at 512 Hz sampling rate. In the example of FIG. 1, anti-aliasing filter 116 and mux 118 are shown as part of filter block 101.

The preamplifier, e.g., sampling amplifier 103, receives the output from slow chop mux 118. Sampling amplifier 103 may be implemented as switched capacitor amplifier and may include input switches and input capacitors (not shown in FIG. 1). Sampling amplifier 103 acts as a preamplifier with programmable gain and outputs sampled and amplified sense voltage signal to integrator circuitry 105.

Integrator circuitry 105 that receives the sampled voltage indicative of the sense voltage from the preamplifier circuitry, switched capacitor gain amplifier 103. Integrator circuitry 105, while in integrate mode, integrates the received sampled voltage, and outputs the integrated sampled voltage to clocked comparator 107. In the example of system 100, integrator circuitry 105 includes amplifier 188 connected to a reference voltage, Vref 165 at the non-inverting input. The output of amplifier 188 connects to the inverting input through capacitor C10 190. The inverting input of amplifier 188 also connects to the switched capacitor resistor RSCR 199, at the output of charge dump circuit 109, and to the non-inverting input of clocked comparator 107.

The preamplifier, sampling amplifier 103, increases the input signal, e.g., the voltage developed across Rsense 114, and presents this gained up input signal to integrator circuitry 105. The output of integrator circuitry 105 output decrements towards VREF 165 at each sample time step (for example 512 Hz, 1024 Hz or some other sample frequency). The integrator output voltage that decrements past VREF, trips clocked comparator 107, which indicates that a fixed amount of charge has been pulled from battery 102. Tripping comparator 107 is considered a count. Also, at each comparator trip, charge dump circuit 109 adds back a fixed amount of charge to the integrator input, e.g., at the connection of feedback capacitor C10 190 to the inverting input of amplifier 188.

Charge dump circuit 109 may deliver a fixed charge to the input of integrator circuitry 105 every time comparator 107 trips. This fixed charge causes the integrator output to shift by a voltage delta equal to a fraction of VREF. Because, for the example of system 100, each comparator trip is defined as one count, then the charge transfer for each comparator trip may correspond to a fixed amount of charge per count. The total charge pulled from battery 102 is the number of counts times a calibrated scaling factor. Scaling is dependent on Rsense 114, capacitor ratios of system 100, the magnitude of VREF and the sampling frequency (Fs). As with any resistor, Rsense 114 may vary, e.g., based on the temperature coefficient for Rsense 114. In the example of system 100 implemented on an integrated circuit (IC), capacitor ratios may be well matched. VREF and Fs may be both trimmed to a desired accuracy. In this manner, the scaling (Qscale) may be controlled over temperature and only dependent on the absolute Rsense variation from part to part. Such part to part variation may be accounted for with an overall scaling trim for each device stored at a memory location accessible to digital circuitry 125, or other processing circuitry. Digital circuitry 125 may also be referred to as digital control circuitry 125, though digital circuitry may include control and calculation functions, data and programmable computer instruction storage, communication and sensing functions.

Digital circuitry 125 receives the output from clocked comparator 107. Digital circuitry 125, in the example of system 100, may also output the control signals 130 that may control the operation of the charge sensing circuit, e.g., switch control signals, enable/disable signals and similar control signals (not shown in FIG. 1). In some examples, digital control 130 may be routed through level shifter circuitry to change the voltage level based on the circuitry to be controlled. For example, changing the voltage level may be useful to ensure the desired gate-source voltage for a switch to operate consistently. Digital circuitry may also output count 129, and/or interrupt signals 127, e.g., in the example of status change, fault and other circuit activity.

In some examples, system 100 may be called a Coulomb counter circuit. By counting the total charge amount used by the electrically powered device and knowing the initial battery charge level at the beginning of life for the battery, the system of this disclosure may determine the state of charge of the battery. The operation, and circuit implementation of this disclosure to determine the battery SoC is configured to operate by consuming only a small percentage of the operating power for the particular application, and therefore have little to no measurable impact on battery longevity. The low power demand of the Coulomb counter circuit of this disclosure, as well as the arrangement including selectable sense resistor 114, and the adjustable capacitance values, may provide an advantage over other Coulomb counter circuits. For example, the battery depletion monitor circuit of this disclosure may be used in a variety of applications, from low power applications with a small battery capacity, to applications with higher power demand and larger capacity electrical energy storage devices.

For a device, such as an implantable medical device, that operate with energy stored in an electrical energy storage device, such as a battery, the output of the battery depletion monitor may be one aspect of battery management for the device. For example, to estimate end of life, display battery level on a user interface, determine when amount of charge consumed exceeds a threshold then generate an alert, such as to instruct a patient to recharge the battery, determine when a rate of battery usage exceeds a threshold and generate an alert to perform a diagnostic test on the device, and other such battery management actions. Actively measuring the battery depletion, e.g., using the circuit of this disclosure, may reduce complexity compared to firmware routines used to estimate battery depletion based on modeling current drain and functional block activity.

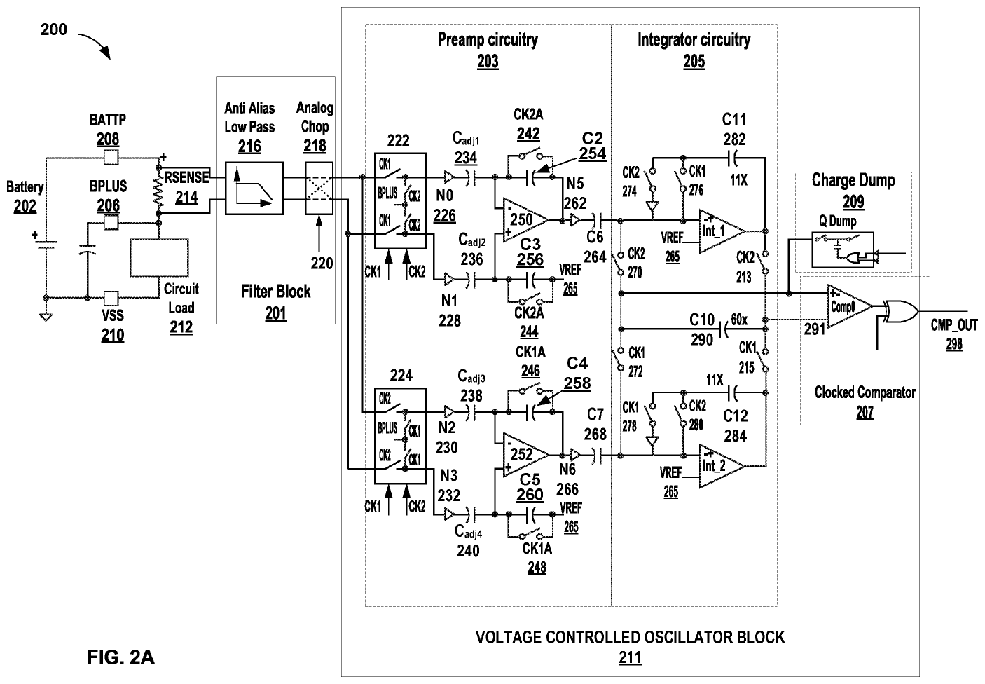

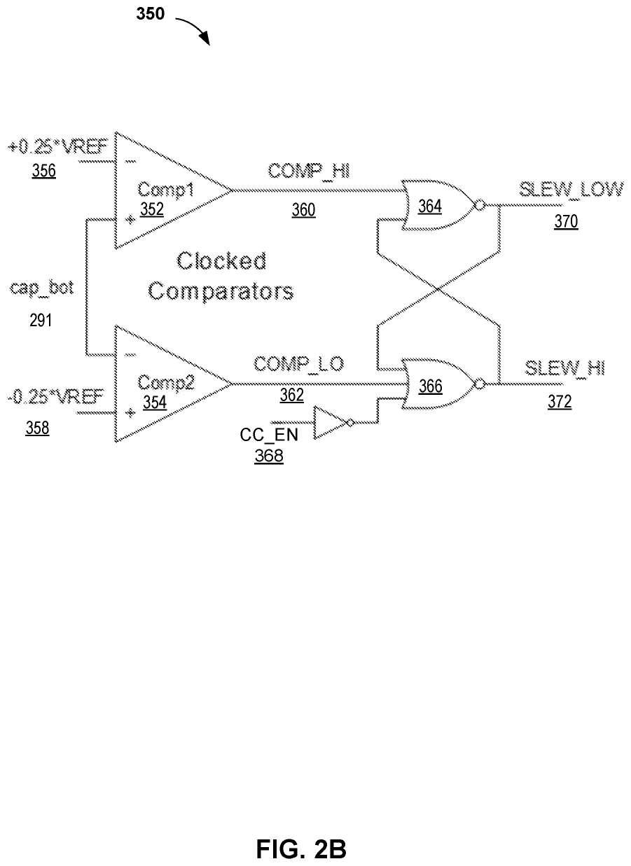

FIG. 2A is a schematic diagram illustrating an example circuit configured to determine an amount of charge per unit time, including a dual path arrangement. System 200 of FIG. 2A is an example implementation of system 100 described above in relation to FIG. 1. Similar to the example of FIG. 1, system 200 includes a charge sensing circuit configured to measure the amount of charge consumed over time, e.g., the amount of electrical energy supplied by battery 202 and consumed by circuit load 212.

In the example of system 200 of FIG. 2A, circuit load 212 connects between Vss 210 and BPLUS 206. Vss 210 connects to the negative terminal of battery 202 and BATTP 208 connects to the positive terminal of battery 202. An additional terminal, BPLUS 206, connects to circuit load 212 and to Vss 210 through C1 204.

The charge sensing circuit includes a sense resistor, Rsense 214, filter block 201, and VCO block 211. In some examples, Rsense 214 may be implemented as a programmable sense resistor with the value of Rsense 214 controlled by digital circuitry, e.g., digital circuitry 125 described above in relation to FIG. 1. Having selectable values of Rsense 214 may provide an advantage for the same charge sensing circuit architecture of this disclosure to be used for a variety of applications as well as to adjust the sensitivity based on the operating mode of circuit load 112. For example, for circuit load 112 operating in a relatively low power mode, selecting a larger value for Rsense 214 may be desirable. Some example values for Rsense 214 may include zero ohms (short circuit), 2 ohms, 4 ohms, 10 ohms, 20 ohms or other similar values. In some examples, the circuitry that implements Rsense 214 may be located separately from other circuitry of the charge sensing circuitry to minimize routing resistance through the sense resistor. In some examples, zero ohms is used when the coulomb counter is disabled, such as when the coulomb counter is duty cycled off and on to further reduce current drain.

In some examples, Rsense 214 may be implemented as a parallel and/or series combination of different resistor types that may have different temperature coefficients. For example, Rsense 214 may be implemented as combinations of p-poly and n-poly resistor types. An n-poly resistor may have a positive temperature coefficient while a p-poly resistor may have a negative temperature coefficient. The combination of resistor types may help cancel the effects of temperature in Rsense 214 during operation.

Filter block 201 includes anti-aliasing filter 216 and analog chop circuit 218. Anti-aliasing filter 216 is configured to suppress aliasing in the subsequent sampled switched capacitor preamplifier circuit 203 and integrator circuit 205 of VCO block 211. Anti-alias filter 216 may be implemented as a linear filter. Therefore, the total integrated energy of the filter output may equal to the total integrated energy at the input. This means that for short duration current pulses, even though the peak output voltage may be suppressed by the low-pass filter function of anti-alias filter 216, the total signal at the output to analog chop circuit 218 and VCO block 211 may be lower in amplitude but spread out in time. In this manner the total energy at the input appears at the filter output even though the peak signal at the output is a smaller percentage of the peak input amplitude.

As described above in relation to FIG. 1, analog chop circuit 218 may be implemented as a slow chop mux between filter 216 and VCO block 211, which has the same or similar characteristics to slow chop mux 118 of FIG. 1. In other words, analog chop circuit 218 receives the output of input filter 216 and feeds VCO block 211 so that VCO block 211 samples the filtered input signal with a positive gain for half of the chop period. For the other half period, analog chop circuit 218 feeds VCO block 211, which takes multiple samples with an inverted gain with respect to the first half period. The average of the two half periods may cancel the input referred offset. VCO block 211 may also use double correlated sampling to further cancel the input referred offset.

As described above, a “slow” chop period means a period that is much longer than the clock period and sample period for system 200. One possible example implementation, may have a sample frequency of 1024 Hz and a five minute analog chop period. For this example implementation, the five-minute chop period (300 seconds) corresponds to ˜155000 clock cycles (e.g., 150 sec*1024 Hz) for each half chop period phase of the chop clock. Each time the chop clock transitions, an error may be introduced in the integrator (e.g., a +1 or −1 count). For a low current load, the total number of counts in a 2.5-minute chop clock phase may be fairly low in this example implementation, e.g., around 8 to 10 counts. At this low current, a +2 count error may be a significant error term, relative to the 8-10 total counts. Using a very slow chop clock relative to the sampling period may attenuate the significance of this error. Some of the error may be mitigated by long term averaging based on sampling with a positive gain alternating with sampling with a negative gain. As long as the error is uncorrelated and centered around zero, much of this error may be suppressed with such averaging.

The analog chop technique of this disclosure may still be effective over time, even for short term temperature changes. For the analog chopping technique to be effective in the short amount of time, the techniques of this disclosure may assume that the offset does not drift significantly over the chop period (e.g., 300 seconds or 5 minutes as described above). In other words, this chop technique works well with steady state conditions which is assumed to be the case for a majority of the time. Examples of exceptions might be rapid heating or cooling of a device that includes the charge sensing circuitry of this disclosure. For example, a medical device implanted in, or worn by a patient that enters a pool, hot tub, sauna or encounters some other significant short term temperature change. Changing the offset may result in short-term error that may not be well canceled. Once the charge sensing circuit stabilizes and reaches steady state, the offset errors are again reduced or canceled.

The techniques of this disclosure to reduce the input referred error may provide advantages over other techniques for handling input referred error. For example, one technique to reduce input referred error may include to calibrate out the input referred offset during manufacturing. Calibration may have some issues that include the test time to acquire the offset may be long and therefore reduce manufacturing efficiency and throughput. In addition, any drift in the input offset caused by temperature, power supplies or circuit component aging can result in significant errors at low current levels. For example, an input offset shift of just four microvolts (4 μV) corresponds to an offset shift of one microamp (1 μA), e.g., for a four ohm resistor setting. For a low power current load operating with a battery current drain of 1 μA, such a shift would result in a 100% error.

In this disclosure, the charge sensing circuit may also be referred to as a coulomb counter, coulomb counter circuit, power consumption circuit or battery depletion circuit. For the charge sensing circuit, the first terminal of Rsense 202 connects to the power supply terminal, BATTP 208, and the second terminal of Rsense 202 connects to circuit load 212. As with Rsense 114 of FIG. 1, Rsense 202 may a sense voltage proportional to an instantaneous load current, e.g., the magnitude of current consumed by circuit load 212.

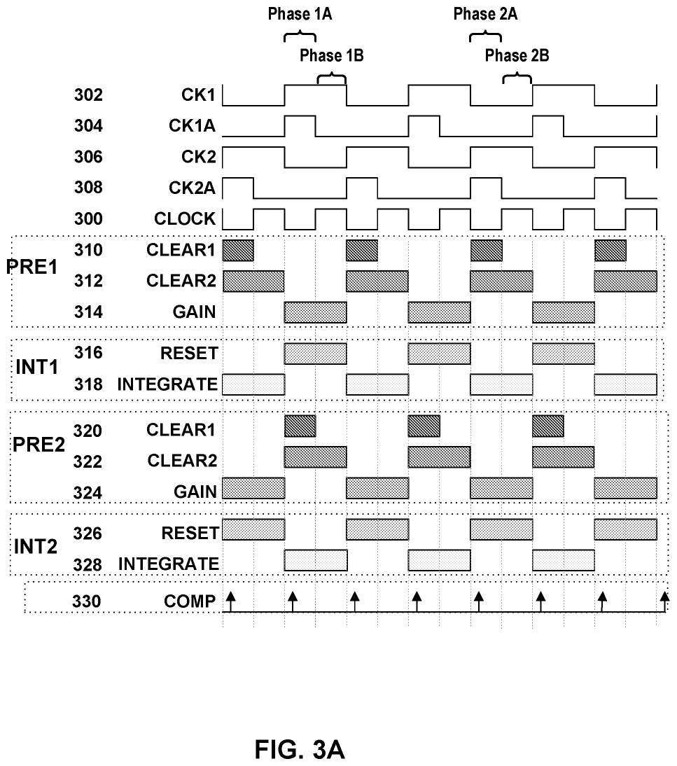

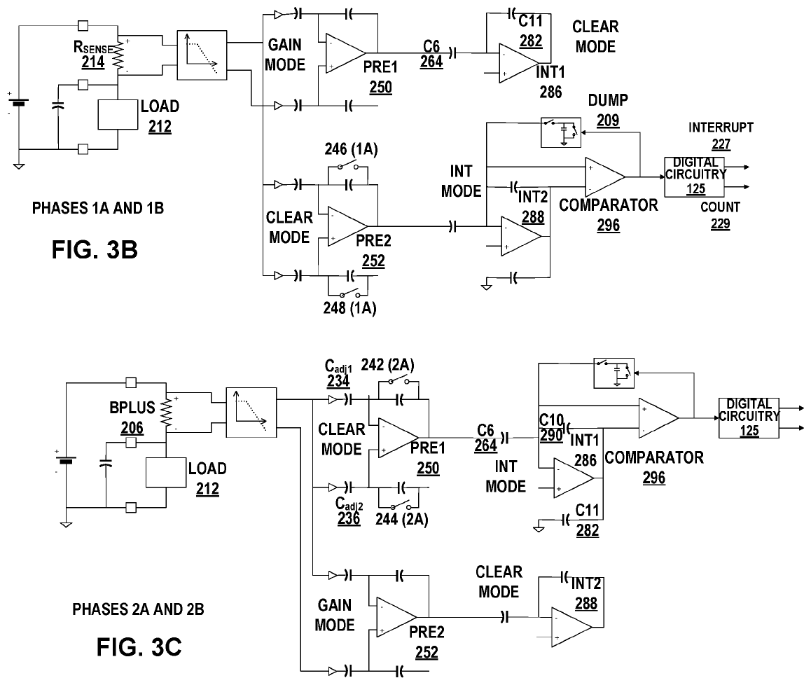

In the example of FIG. 2A, VCO block 211 includes preamplifier circuit 203, integrator circuit 205, comparator circuit 207 and charge dump circuit 209. In the example implementation of FIG. 2A, both preamplifier circuit 203 and integrator circuit 205 have dual paths with opposite clock phasing. The clock phasing may also be described as complementary clock phasing because while one path is in gain phase the other path is in clear phase, and vice versa (see also FIG. 3A).

Effectively, the architecture and operation of system 200 implements a bilinear sampling of the input signal, e.g., the filtered voltage from across Rsense 214. In this manner, for a given clock rate (such as 512 Hz, 256 Hz or some other clock rate), preamplifier circuit 203 samples the input voltage signal on each half phase of the clock rate, so that the effective sample rate is twice the clock rate (e.g., 1024 Hz for a 512 Hz clock rate or 512 Hz for a 256 Hz clock rate). One desirable consequence of this bilinear sampling is that the composite integrator output voltage to comparator 207 is valid throughout the entire clocking cycle.

In addition, VCO block 211 is implemented with switched capacitor circuits that quantize the VCO output period in integer multiples of the sampling frequency (Fs). Any residual error due to quantizing is retained and contributes to the next period timing. Over a long-term average, the quantized VCO frequency asymptotically approaches an ideal non-quantized frequency.

In preamplifier 203, the output of analog chop circuit 218 connects to both paths, called the upper path and lower path in this disclosure, for convenience. The upper path of preamplifier 203 includes switch matrix 222, amplifier 250, while the lower path includes switch matrix 224 and amplifier 252.

Switch matrix 222 receives two clock signals CK1 and CK2 (see also FIG. 3A for signal timing). Switch matrix 222 receives the filtered and slow chopped input signal through two switches configured to operate based on clock signal CK1. A first output terminal of switch matrix 222 connects to the inverting input terminal of amplifier 250 through source follower NO 226 and adjustable capacitor Cadj1 234. The second output terminal of switch matrix 222 connects to the non-inverting input terminal of amplifier 250 through source follower N1 228 and adjustable capacitor Cadj2 236. Switch matrix 222 also includes switches that connect the input terminals of amplifier 250 to BPLUS 206 based on clock signal CK2.

The value of adjustable capacitors Cadj1 234, Cadj2 236, Cadj3 238 and Cadj4 240, along with the timing and operation of the switches of system 200 may be controlled by digital circuitry including one or more processors, such as digital circuitry 125 described above in relation to FIG. 1. Adjusting the value of these input capacitors to preamplifier 203 adjusts the gain of preamplifier 203. The value of the adjustable capacitors may be based on a selectable multiple of a nominal capacitor value (Cnom), such as approximately 1 picofarad (pf), 0.5 pf or some other value depending on the application for system 200. For example, command signals from the digital circuitry may set the value for any of the adjustable capacitors to be some multiple of the nominal value e.g., two times Cnom, eight times Cnom, 32 times Cnom or some other capacitance value. In some examples, other capacitors in preamplifier circuit 203, integrator circuit 205 may also be based on some multiple of Cnom. The ratios of the capacitors may set gain, timing, integrator step size, coulomb count scaling or other functions of system 200.

Amplifier 250 includes a feedback circuit with capacitor C2 254 connected between the output terminal of amplifier 250 and the inverting input terminal. Switch 242 may directly connect the output terminal of amplifier 250 and the inverting input terminal by shorting across capacitor C2 254. Switch 242 operates according to clock signal CK2A. Switch 244, which also operates based on clock signal CK2A directly connects the non-inverting input terminal of amplifier 250 to the reference voltage VREF 265 when closed. The non-inverting input terminal of amplifier 250 connects to VREF 265 through capacitor C3 256 when switch 244 is open. In some examples, capacitors C2 254 and C3 256 may be set to a fixed value of two times Cnom. The output terminal of amplifier 250 connects to the upper path of integrator circuit 205 through source follower N5 262 and capacitor C6 264. Capacitor C6 264 may be set to eleven times Cnom, in some examples.

For the lower path of preamplifier 203, switch matrix 224 receives the two clock signals CK1 and CK2. Switch matrix 224 receives the filtered and slow chopped input signal through two switches configured to operate based on clock signal CK2, opposite to the similar switches in switch matrix 222. A first output terminal of switch matrix 224 connects to the inverting input terminal of amplifier 252 through source follower N3 230 and adjustable capacitor Cadj3 238. The second output terminal of switch matrix 224 connects to the non-inverting input terminal of amplifier 252 through source follower N3 232 and adjustable capacitor Cadj2 240. Switch matrix 224 also includes switches that connect the input terminals of amplifier 252 to BPLUS 206 based on clock signal CK1.

Amplifier 252 includes a feedback circuit path with capacitor C4 258 connected between the output terminal of amplifier 252 and the inverting input terminal. Switch 246 may directly connect the output terminal of amplifier 252 and the inverting input terminal by shorting across capacitor C4 258. Switch 246 operates according to clock signal CK1A. Switch 248, which also operates based on clock signal CK1A directly connects the non-inverting input terminal of amplifier 252 to the reference voltage VREF 265 when closed. The non-inverting input terminal of amplifier 252 connects to VREF 265 through capacitor C5 260 when switch 248 is open. In some examples, capacitors C4 258 and C5 260 may be set to a fixed value of two times Cnom. The output terminal of amplifier 252 connects to the lower path of integrator circuit 205 through source follower N6 266 and capacitor C6 268. Capacitor C6 268 may be selected as eleven times Cnom, in some examples. In other examples, the capacitor values may differ which provides different capacitor ratios depending on the application and desired operation for system 200.

Integrator circuit 205 has an upper and lower path that connects respectively to the upper and lower path of preamplifier 203, as described above. For the upper path, the inverting input of amplifier 286 connects to the output of amplifier 250 through source follower N5 262 and capacitor C6 264. The non-inverting input terminal of amplifier 286 connects to VREF 265. The feedback path for amplifier 286 includes two switches. Switch 276 operates according to clock CK1 and when closed connects the output terminal of amplifier 286 to the inverting input terminal through capacitor C11 282 in an integrator configuration. Switch 274 operates according to clock CK2 and when closed connects the output terminal of amplifier 286 to circuit ground, e.g., Vss 210 through capacitor C11 282. In some examples, amplifier 286 may be implemented as an operational transconductance amplifier (OTA).

The upper path input terminal to integrator 205, the inverting input terminal of amplifier 286, also connects through switch 270 to the non-inverting input of clocked comparator 292 of comparator circuit 207, the output terminal of charge dump circuit 209, and to the inverting input of clocked comparator 292 through capacitor C10 290. Switch 270 operates according to clock CK2. In some examples, capacitor C10 290 may be selected as sixty times Cnom (60×Cnom). The output terminal of amplifier 286 connects to the inverting input of clocked comparator 292 through switch 213, which operates according to clock CK2.

For the lower path, the inverting input of amplifier 288 connects to the output of amplifier 252 through source follower N6 266 and capacitor C7 268. The non-inverting input terminal of amplifier 288 connects to VREF 265. The feedback path for amplifier 288 also includes two switches. Switch 280 is similar to switch 276, but operates according to clock CK2, and when closed connects the output terminal of amplifier 288 to the inverting input terminal through capacitor C12 284 in an integrator configuration. Second switch 278 operates according to clock CK1 and when closed connects the output terminal of amplifier 288 to circuit ground through capacitor C12 284.

The lower path input terminal to integrator 205, the inverting input terminal of amplifier 288, also connects through switch 272 to the non-inverting input of clocked comparator 292 of comparator circuit 207, the output terminal of charge dump circuit 209, and to the inverting input of clocked comparator 292 through capacitor C10 290. Switch 272 operates according to clock CK1. The output terminal of amplifier 288 connects to the inverting input of clocked comparator 292 through switch 215, which operates according to clock CK1. The comparator 207 output 298 is the output of the VCO 211. The frequency of this signal (298) is directly proportional to the battery current.

The dual path arrangement of system 200 may provide an advantage of reduced clock rate compared to a single path architecture. In other examples, system 200 may operate by doubling the clock rate and eliminate one of the two preamps and one of the two integrators. This may reduce complexity and circuit components but does use a higher clock rate to get the same sampling performance. Nominally, other aspects of the circuit may be arranged double the current drain in the remaining preamp and integrator so the overall current drain difference would be the same as the dual path architecture.

FIG. 2B is a schematic diagram illustrating an example implementation of the clocked comparator circuit of this disclosure. Circuit 350 includes one example implementation of a clocked comparator, such as clocked comparator 207 described above in relation to FIG. 2A.

In the example of circuit 350, cap_bot 291 connects to node 291 depicted in FIG. 2A. The node at cap_bot 291 connects to the non-inverting terminal of comp1 352 and the inverting terminal of comp2 354. A reference voltage 356 connects to the inverting terminal of comp1 352, while reference voltage 358 connects to the non-inverting terminal of comp2 354. Reference voltage 358 is the same magnitude but opposite polarity of reference voltage 356, which in the example of FIG. 2B is 0.25 V.

The output of comp1 352, comp_hi 360, connects to NOR gate 364. The output of comp2 354, comp_lo 362, connects to NOR gate 366. In the example of FIG. 2B, a Coulomb counter enable terminal, CC_EN 368 also connects to NOR gate 366. The output of NOR gate 364 is SLEW_LOW 370, which also connects to an input of NOR gate 366. Similarly, the output of NOR gate 366 is SLEW_HI 372, which connects to an input of NOR gate 364.

The outputs SLEW_LOW 370 and SLEW_HI 372 determine the “direction” of the VCO, e.g., VCO 211 described above in relation to FIG. 2A. Each time the chop inverts the input signal, e.g., from mux 218 of FIG. 2, to the VCO, then the VCO runs “backwards” until the integrator output overranges and trips the slew_hi/slew_low latch. Tripping the latch causes the VCO to reverse “direction,” so that the charge dump inverts, e.g., the outputs of charge dump circuit 209 of FIG. 2A, and comparator 207 of FIG. 2A output inverts. The polarity of the charge dump circuit is controlled by the slew_hi/slew_lo latch which sets the VCO “direction.”

FIGS. 3A, 3B and 3C describe the operation of the example arrangement of system 200 in more detail. FIG. 3A is a timing chart illustrating an example operation of the Coulomb counter circuit of FIG. 2. FIGS. 3B and 3C are schematic diagrams illustrating the different phases or modes of operation for the charge sensing circuit of this disclosure according to the clock signal timing. Some reference numbers have been omitted in the figures and description to simplify the explanation of the circuit operation. The below description may focus on one path at a time, but the operation description may apply equally to both the upper path and lower path.

One of the aspects of the circuit operation is minimizing the input referred offset of preamplifier 203, as described above in relation to FIGS. 1 and 2 with double correlated sampling. For each circuit path in turn, the amplifier, PRE1 250 or PRE2 252, of preamplifier 203 is first auto zeroed with the inputs tied together at a zero volts input signal. Next control signals operated the switches causing the respective amplifier to be released, leaving a residual charge at the amplifier output to the respective integrator path. With the respective amplifier input held at zero volts, the respective integrator is autozeroed with the preamplifier output offset. Then the integrator is released. The net effect is a double cancellation of the input referred offset. This reduces the channel input referred offset to a practical range, which in some examples, is in the range of ±30 μV to 80 μV.

As shown in FIG. 3C, amplifier 250 (PRE1) is in clear mode while integrator 1 (INT1 286) is in the gain phase, also called INT mode. The clear phase for the preamplifier is split into two quarter periods, phase 2A 310 and phase 2B 312 for PRE1 250 and phase 1A 320 and 1B 322 for PRE2 252. During the first portion of the clear phase (CK1A 304 & CK2A 308), the input capacitors, e.g., Cadj1 234 and Cadj2 236 for PRE1 250, are shorted together to BPLUS 206 at switch matrix 222 described above in relation to FIG. 2. Amplifier PRE1 250 is also configured into a unity gain topology with the positive preamp input shorted to VREF, e.g., switches 242 and 244 are closed. This configuration pre-charges the input capacitors for the preamp to the voltage at BPLUS, which is close in voltage to the common mode voltage for the VSense, the voltage across sense resistor Rsense 214. In other words, during CLEAR1 310, the preamplifier is configured in unity gain to store the preamplifier offset on the preamplifier input capacitors.

At the end of the first quarter clear phase 310, the control signals cause switches 242 and 244 to open and PRE1 250 is reconfigured as a differential amplifier. The input voltage at the input capacitors is held at BPLUS 206 for phase 2B 312 (or phase 1B 322 for PRE2 252), which allows any offset caused by the switching to settle at the output terminal for PRE1 250 at the end of the second quarter clear phase 2B. This settled voltage is the voltage that the upper path integrator, INT1 286, receives at the end of the integrator gain phase (INT Mode 318). Said another way, for phase 2B 312, after CLEAR1 310, the preamplifier is configured in gain mode, but with the inputs shorted together. During phase 2B, the output offset of the preamplifier is stored on the integrator input capacitors.

During the upper path integrator gain phase (INT Mode 318), the integrator capacitor (C10 290) is switched over to the integrator amplifier, INT1 286, as the feedback capacitor from the inverting input to the output. At the point in time that the integrator capacitor is switched in, the upper path preamplifier PRE1 250 is at the end of the preamp gain phase 314 and transitioning to the clear phase 312. From the integrator point view, the preamplifier output signal is moving from:

$$VOG = VREF + VOS + GAIN * VIN$$

to the preamplifier clear voltage VOC=VREF+VOS. The integrator output voltage shift during the gain phase will be equal to:

$$VINT\_delta = 11 / 60 * ( VOG - VOC ) = 11 / 60 * GAIN * VIN ,$$

where 11/60 is the ratio of C6 264 and C10 290. Note that the operation sequence described above results in a first order cancellation of the preamplifier offset, and applies to both the upper path operation and lower path operation. During each respective integration phase 318 and 328, the integrator counts down and the clocked comparator trips, producing a count 330, indicating the specified amount of energy has been consumed from the battery by the load.

During the upper path integrator clear phase, also referred to as reset phase 316, the integrator (feedback) capacitor C10 290 is switched out of the circuit and the clear capacitor, C11 282, is switched in the feedback of the upper path integrator INT1 286. During reset phase the preamplifier VOG minus the input offset of the INT1 286 is stored on the integrator input cap C6 264. Note that the clear capacitor C11 282 for the integrator reset phase has been precharged to the integrator output voltage, therefore clear capacitor C11 282 may also be referred to as the precharge capacitor for INT1 286. This limits the output swing for the INT1 286 during the reset phase 316. In other examples, using a switch to place INT1 286 in unity gain, without C11 282, the integrator output volage would always swing from VINT to VREF. In contrast, the reset feedback cap C11 282, limits the integrator output swing to −GAIN*VSense. For small battery currents, where VSense is small, the output swing may be correspondingly small, which may result in reduced settling time at low VSense signals, compared to other circuit arrangements.

In this manner, for each of the upper path and lower path, the inverted phasing may improve settling times, compared to other techniques. When the respective path of preamplifier 203 is in gain mode the integrator is in reset mode. The voltage stored on the integrator input cap, C6 264 or C7 268, may be driven to the preamplifier output offset in the next phase when the preamplifier is in clear mode and the integrator accumulates this stored charge.

In this disclosure, the integrate mode may also be referred to as the gain mode for the integrator circuit and the reset mode may also be referred to as the clear mode for the integrator circuit. Similarly, for the preamplifier circuit, the clear modes may also be referred to as reset modes.

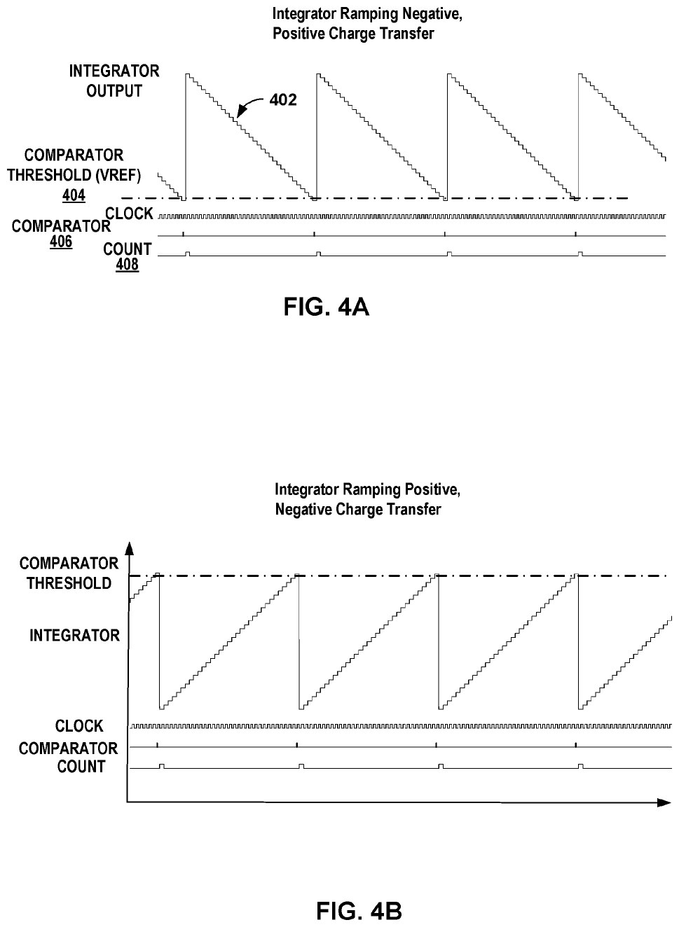

FIGS. 4A and 4B are timing diagrams illustrating an example operation of components of a Coulomb counter circuit according to one or more techniques of this disclosure. As described above in relation to FIGS. 1-3C, the integrator output decrements 402 towards VREF 404 at each sample time step, based on the selected sample frequency (Fs). Once the integrator decrements past VREF 404, the clocked comparator 406 is tripped indicating that a fixed amount of charge has been pulled from the battery.

Tripping the comparator is considered a count 408. Selecting the values for components in systems 100 and 200 shown in FIGS. 1 and 2 may set the scaling for each count (Qscale). For purposes of explanation, an example scaling may be approximately 20 μC/count (micro Coulombs per count). Thus, processing circuitry for the system, e.g., included in digital circuitry 125 of FIGS. 1, 3B and 3C, may calculate the total charge pulled from the battery as the number of counts times the calibrated scaling factor. As described above in relation to FIG. 1, because each comparator trip is defined as one count, then the charge transfer for each comparator trip may correspond to a fixed amount of charge per count. At each comparator trip 406, a fixed amount of charge is added back to the integrator output by the charge dump circuit, as described above in relation to FIG. 1.

In terms of voltage in the example of system 200, the integrator output voltage for each path may be shifted by a voltage equal to VREF*10/60, where VREF is the system reference voltage, e.g., VREF 165 of FIG. 2, and the 10/60 is set by capacitor ratios. Other capacitor ratios may be useful based on the application or desired performance for the charge sensing circuit of this disclosure. The example of FIG. 4B depicts another example implementation of the charge sensing circuit of this disclosure in which the integrator circuit ramps in a positive direction and operates with a negative charge transfer.

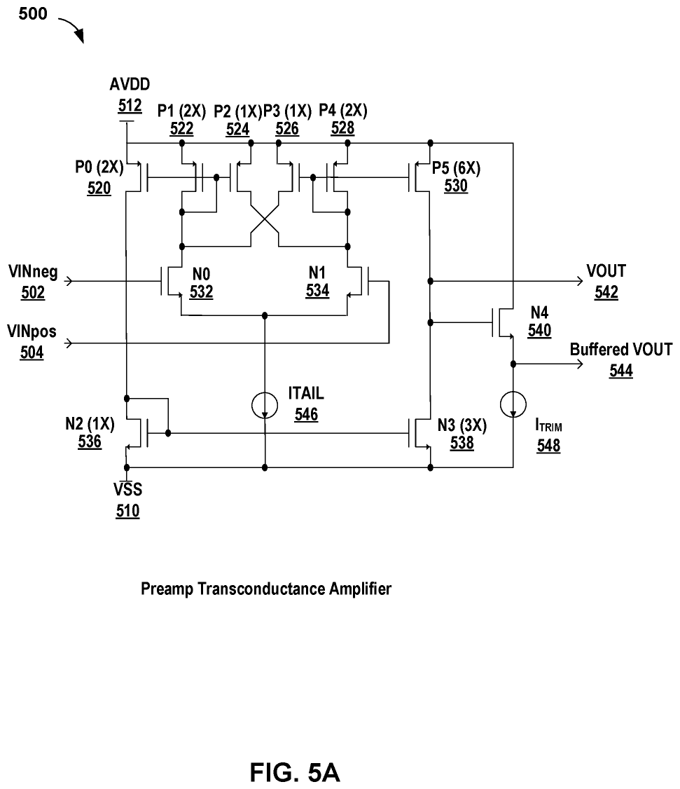

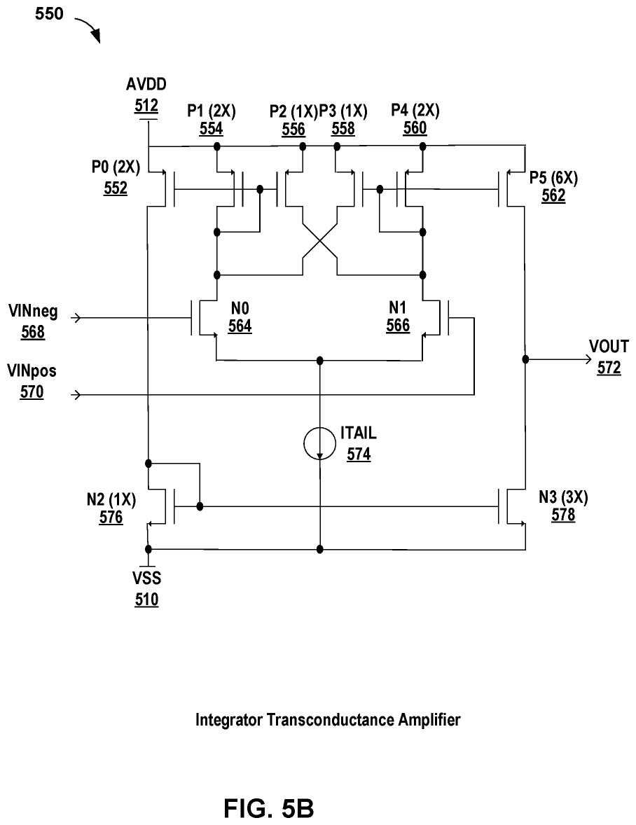

FIG. 5A is a schematic diagram illustrating an example implementation of amplifier components for the preamplifier of the charge sensing circuitry according to one or more techniques of this disclosure. The example circuit architecture of amplifier 500 is an example of amplifier 103, 250 and 252 described above in relation to FIGS. 1-3C.

In amplifier 500, supply voltage AVDD 512 connects to the source of p-channel transistors P0 520, P1 522, P2 524, P3 526, P4 528 and P5 530. The gates of P0 520, P1 522, and P2 524 connect to the drain of n-channel transistor NO 532. The gates of P3 526, P4 528 and P5 530 connect to the drain of n-channel transistor N1 534. The drains of P1 522 and P3 526 connect to the drain of NO 532. The drains of P2 524 and P4 528 connect to the drain of N1 534. The sources of NO 532 and N1 534 connect through current source Itail 546 to Vss 510. Vss 510 corresponds to Vss 110 and Vss 210 described above in relation to FIGS. 1 and 2.

The gate of NO 532 is the negative input terminal VINneg 502, while the gate of N1 532 is the positive input terminal VINpos 504. The output terminal VOUT 542 is the node connecting the drain of P5 530 and drain of N3 538. Buffered output VOUT 544, is the source of N4 540, which also connects through Itrim 548 to Vss 510. The drain of P0 520 connects to the drain and gate of N2 536 and gate of N3 538, with the source of N2 536 and the source of N3 538 connected to Vss 510.

The example OTA architecture of amplifier 500 uses positive feedback (2X gain boost) in the p-channel mirrors (P1-4) and mirror multiplication (P4-5 & N2-3) to achieve high transconductance gain at reduced supply current. Compared to a simple telescoping OTA, this transconductance (GM) boost topology achieves equivalent transconductance while reducing the AVDD 512 supply current by a factor of 3×. The additional poles in this topology due to the current mirrors (P0-1, P4-5 and N2-3) may impact stability for the preamplifier. The possible instability may be mitigated by reducing the gate area on these current mirrors and by operating at higher bias currents. Increasing the bias current helps in two ways. First, the pole frequencies at the mirrors are increased in direct proportion to the bias current. Second, GM is boosted in direct proportion to the bias current. The GM boost may improve the overall settling response because it reduces the settling time constant (C/GM), increasing the number of time constants in a clock half period. The reduced stability may result in some overshoot and ringing in the settling response, but the reduced settling time constant may more than make up for any instability with reduced overall settling time. In this manner, the GM boosting technique for amplifier 500 of FIG. 5A meets the settling time for the preamplifier circuit, e.g., preamplifier 203 of FIG. 2, at a significantly reduced current drain compared to other techniques.

FIG. 5B is a schematic diagram illustrating an example implementation of amplifier components for the integrator circuit of the charge sensing circuitry according to one or more techniques of this disclosure. In the example of FIG. 5B, amplifier 550 is an example of amplifier 188, 286 and 288 described above in relation to FIGS. 1 and 2.

In amplifier 550, supply voltage AVDD 512 connects to the source of p-channel transistors P0 552, P1 554, P2 556, P3 558, P4 560 and P5 562. The gates of P0 552, P1 554, and P2 556 connect to the drain of n-channel transistor NO 564. The gates of P3 558, P4 560 and P5 562 connect to the drain of n-channel transistor N1 566. The drains of P1 554 and P3 558 connect to the drain of NO 564. The drains of P2 554 and P4 560 connect to the drain of N1 566. The sources of NO 564 and N1 566 connect through current source Itail 574 to Vss 510. As with FIG. 5A, Vss 510 corresponds to Vss 110 and Vss 210 described above in relation to FIGS. 1 and 2.

The gate of NO 564 is the negative input terminal VINneg 568, while the gate of N1 566 is the positive input terminal VINpos 570. The output terminal VOUT 572 is the node connecting the drain of P5 562 and drain of N3 578. The drain of P0 552 connects to the drain and gate of N2 576 and gate of N3 578, with the source of N2 576 and the source of N3 578 connected to Vss 510.

The example integrator OTA topology is similar to the circuit for preamplifier OTA circuit 500 of FIG. 5A. For the integrator OTA, one difference between amplifier 550 and amplifier 500 is in operation of tail current source 574. During normal integration mode, e.g., 318 and 328 of FIG. 3, the bias current, Itail 574 is set to a predetermined value, which in some examples may depend on the selected sample rate (Fs). During a charge dump, control signals increase Itail 574, which in some examples may be increased by a factor of three or more. The increased tail current may reduce the settling time for any clock periods where a large charge dump is applied to the integrator, as described above in relation to FIGS. 1-3. As described above, the charge dump occurs for integration cycles where the comparator has tripped.

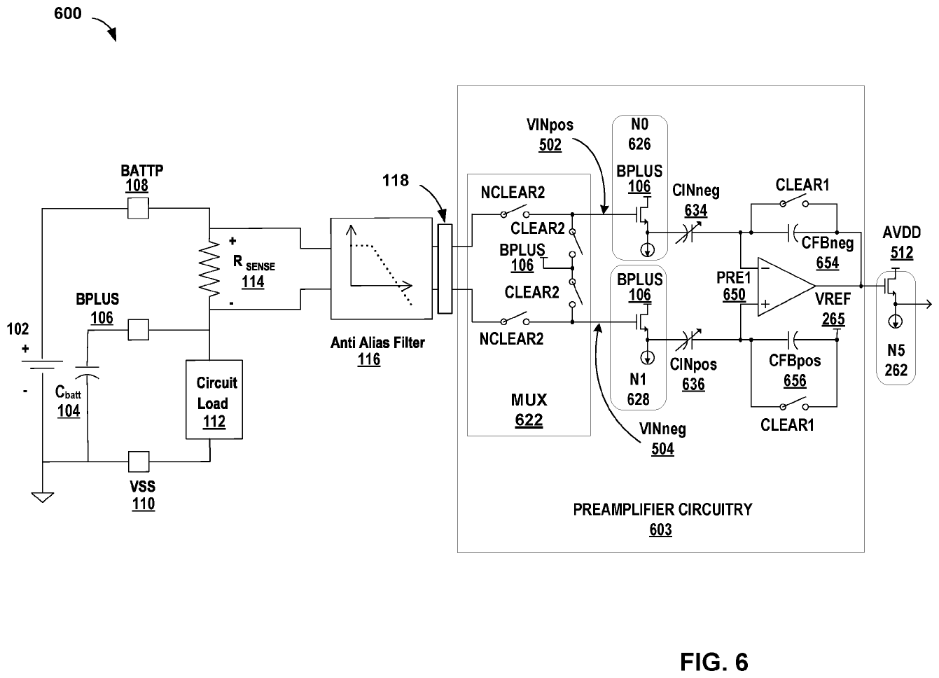

FIG. 6 is a schematic diagram illustrating an example switched capacitor preamplifier circuit according to one or more techniques of this disclosure. System 600, in the example of FIG. 6, provides additional detail regarding the operation of the switched capacitor sampling preamplifier circuit described above in FIGS. 1, 2, 3A-3B and 5A. Components with the same references numbers as described above in relation to FIGS. 1 and 2 have the same functions and characteristics as described above.

In general, source followers NO 626 and N1 628, connected to BPLUS 106, are configured to buffer the output of anti-aliasing low pass filter 116 and prevent any charge pumping from the preamplifier switched capacitor clocks from inducing an offset voltage at the output of the low pass filter. The source followers may also prevent loading from the gain stage of preamplifier circuitry 603 from causing excess settling time. Auto-zeroing using multiplexor (mux 622) may reduce or null offset or offset error that may be caused by NO 626 and N1 628. The variable input capacitor CIN, e.g., CINneg 634 and CINpos 636 sets the programmable gain for preamplifier circuitry 603. Capacitors CINneg 634 and CINpos 636 correspond to Cadj1 234 and Cadj2 236 described above in relation to FIG. 2. In some examples, the programmable gain feature may be omitted for the coulomb counter of this disclosure. In the example of FIGS. 2 and 6, the programmable gain may allow changes to the upper input current range for the coulomb counter circuit of this disclosure. Source follower N5 262 buffers the preamplifier output, e.g., the output terminal of PRE1 650, to drive the next stage integrator circuitry. This buffering reduces the capacitive load on preamplifier circuitry 603 and improves setting time (e.g., reduced current). The offset of the output source follower N5 262 may be reduced or nulled with the second stage of autozero in the integrator stage, as described above in relation to FIGS. 1 and 2.

In more detail, preamplifier circuitry 603 is a switched capacitor circuit with two clock phases or modes-reset and gain, as described above in relation to FIGS. 3A-3C. During the reset phase or clear mode, the input mux 622, e.g., corresponding to switch matrix 222 and 224 of FIG. 2, disconnects the circuit from the input (anti-alias filter output) and shorts both mux outputs VINneg 502 and VINpos 504 to BPLUS 106. As shown in FIG. 6, in clear mode, 312 or 322 of FIG. 3, mux 622 may open the switches labeled NCLEAR2, and close the switches labeled CLEAR1. This switch arrangement allows clearing of each respective path (e.g., upper path and lower path as shown in FIG. 2) of the preamplifier with a zero volts input during clear mode. Source followers NO 626 and N1 628 buffer the output of mux 622 to prevent injecting switching charge noise from the positive and negative input caps (e.g., CINneg 634 and CINpos 636) back into the anti-alias filter. In some examples, charge coupling from the input caps may induce gain and offset errors at the filter output. Buffering with the source followers may reduce or prevent charging currents from flowing back into anti-alias filter 116.

In some examples, the source followers are constructed using n-channel transistors with the well tied to the source. The provides a buffer gain that is very close to unity with an output offset of the N threshold (˜−0.5 v). The currents for the source follower are derived from the bias trim voltage (NBIAS) using, for example, 2.5 v N-channel devices. To prevent excess drain voltage across these 2.5 v devices, cascode devices are added in series with the drain. The gate voltage for these cascode devices is VREF, e.g., VREF 265 of FIG. 2.

The switch cap gain stage of preamplifier circuitry 603 is fully differential. Besides providing the desired gain, the preamplifier block may level shift the filtered and slow chopped VSense signal from a large common mode voltage level near BPLUS 106 down to a signal centered around VREF 265. The differential structure may provide good common mode rejection of the BPLUS battery voltage, which may be useful to maintain insensitivity to the DC level of the battery voltage, e.g., as the battery voltage changes with use, and to suppress battery voltage noise from coupling into the preamp output.

The preamp gain is set by a capacitive ratio (CIN/CFB). CIN, e.g., CINneg 634 may be register controlled over a range of settings. In some examples, the range may include from 200 fempto-Farad (fF) to 6.4 pF in steps of Cnom, as described above in relation to FIG. 2. The feedback capacitance, CFB, e.g., CFBneg 654 and CFBpos 656 may be a fixed. As described above in the example of FIG. 2, each CFB is set at twice Cnom, and provide a gain range setting from 0.5 v/v up to 16 v/v in 0.5 v/v steps, for the example of FIG. 2. In some examples, very low gain settings may be impractical because the preamplifier may operate in an unstable region with excessive ringing. As described above in relation to FIG. 1, the selectable gain may provide an advantage over other types of Coulomb counter circuits, by making the Coulomb counter of this disclosure adaptable to a variety of applications.

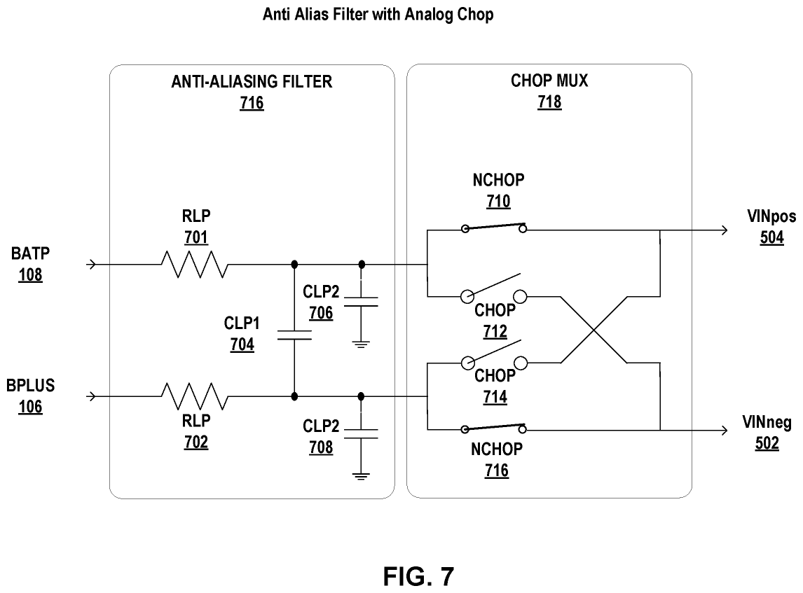

FIG. 7 is a schematic diagram illustrating an example anti-aliasing low pass filter and chop multiplexor according to one or more techniques of this disclosure. The circuit of FIG. 7 is an example implementation of filter 116 and 216 and analog chop mux 118 and 218 described above in relation to FIGS. 1 and 2. In other examples, anti-aliasing low pass filter and analog chop mux may be implemented using a variety of other arrangements.

In the example of FIG. 7, BATTP 108 connects to a first terminal of capacitor CLP2 706 and of capacitor CLP1 704 through resistor RLP 701 of anti-aliasing filter 716. A second terminal for capacitor CLP2 706 connects to circuit ground, which may be Vss 110 in some examples, as described above in relation to FIG. 1. A second terminal of CLP1 704 connects to ground through capacitor CLP 708 and connects to BPLUS 106 through resistor RLP 702.

BATTP 108 further connects to a first input terminal of chop mux 718 through RLP 701. BPLUS connects to a second input terminal of chop mux 718 through RLP 702. In this manner, chop mux 718 receives a low-pass filtered VSense signal generated by current through Rsense 114, as described above in relation to FIG. 1.

In operation, when NCHOP 710 and NCHOP 716 are closed and conducting, the VCO block samples the filtered input signal with a positive gain for half of the chop period. In other words, VINpos 504 receives BATTP 108 and VINneg 502 receives BPLUS 106. When the digital control signals cause NCHOP 710 and NCHOP 716 to open and CHOP 712 and CHOP 714 to close, then the VCO block takes multiple samples with an inverted gain, as described above in relation to FIG. 1. The average of the two half periods cancels the input offset.

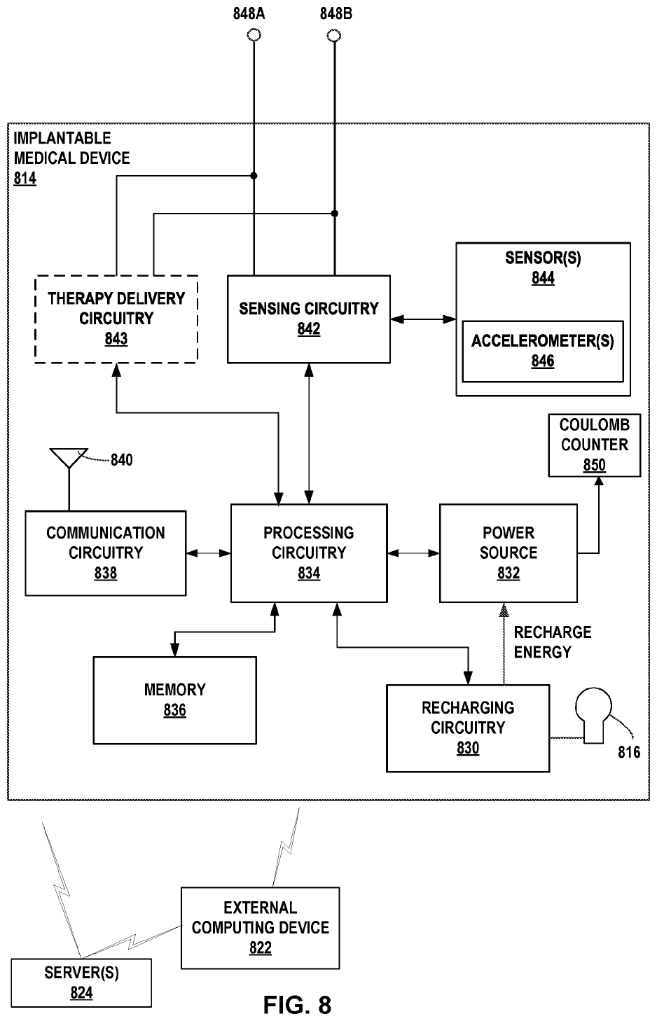

FIG. 8 is a functional block diagram illustrating an example configuration of an implantable medical device (IMD) including an example Coulomb counter circuit of this disclosure. A medical device, including an IMD is just one example application of the Coulomb counter circuit of this disclosure described above in relation to FIGS. 1-7.

In the illustrated example, functional blocks of IMD 814 include receive coil 816, recharging circuitry 830, rechargeable power source 832, processing circuitry 834, memory 836, communication circuitry 838, communication antenna 840, sensing circuitry 842, sensor(s) 844 including accelerometer(s) 846, and electrodes 848A and 848B (collectively, “electrodes 848”). Although the illustrated example includes two electrodes 848, in other examples IMD 814 may be coupled to more than two electrodes 848.

Processing circuitry 834 may include fixed function circuitry and/or programmable processing circuitry. Processing circuitry 834 may include any one or more of a microprocessor, a controller, a digital signal processor (DSP), an application specific integrated circuit (ASIC), a field-programmable gate array (FPGA), or equivalent discrete or analog logic circuitry. In some examples, processing circuitry 834 may include multiple components, such as any combination of one or more microprocessors, one or more controllers, one or more DSPs, one or more ASICs, or one or more FPGAs, as well as other discrete or integrated logic circuitry. The functions attributed to processing circuitry 834 herein may be embodied as software, firmware, hardware, or any combination thereof.

Sensing circuitry 842 is coupled to electrodes 848. Sensing circuitry 842 may sense signals from electrodes 848, e.g., to produce a cardiac EGM, to facilitate monitoring the electrical activity of the heart, as well as sense nerve activity, muscle activity and other bioelectrical signals. Processing circuitry 834 may receive indications from sensing circuitry 842 to determine heart rates or heart rate variability, or to detect arrhythmias (e.g., tachyarrhythmias or bradycardia), patient breathing rhythm, biological impedance, or other bioelectrical signals via electrodes 848. Sensing circuitry 842 also may monitor signals from sensors 844, which may include one or more accelerometers 846, pressure sensors, temperature sensors and/or optical sensors, as examples. In some examples, sensing circuitry 842 may include one or more filters and amplifiers for filtering and amplifying signals received from electrodes 848 and/or sensors 844.

Sensing circuitry 842 may also provide one or more digitized cardiac EGM signals to processing circuitry 834 for analysis, e.g., for use in cardiac rhythm discrimination as well as other digitized bioelectrical signals. In some examples, processing circuitry 834 may store the digitized bioelectrical signals in memory 836. Processing circuitry 834 of IMD 814, and/or processing circuitry of another device that retrieves data from IMD 814, may analyze the bioelectrical signals.

In some examples, IMD 814 may include therapy delivery circuitry 843. Therapy delivery circuitry 843 may be configured to output electrical stimulation therapy to target tissue of the patient, such as to cardiac tissue, nerve tissue and similar patient tissue. In some examples, processing circuitry 834 may control one or more parameters of electrical stimulation from therapy delivery circuitry 843 based on bioelectrical signals sensed by sensing circuitry 842. For example, processing circuitry 834 may determine that ventricular contraction is later than expected, e.g., a duration since a previous contraction exceeds a duration threshold. Processing circuitry may cause therapy delivery circuitry 843 to output electrical stimulation therapy in the form of a pacing pulse to cause the heart of the patient to contract.

Communication circuitry 838 may include any suitable hardware, firmware, software, or any combination thereof for communicating with another device, such as external computing device 22, another networked computing device, or another IMD or sensor. Under the control of processing circuitry 834, communication circuitry 838 may receive downlink telemetry from, as well as send uplink telemetry to external computing device 822, servers 824 or another device with the aid of an internal or external antenna, e.g., antenna 840. In addition, processing circuitry 834 may communicate with a networked computing device via external computing device 822 and a computer network, such as the Medtronic CareLink® Network operating on servers 824. Antenna 840 and communication circuitry 838 may be configured to transmit and/or receive signals via inductive coupling, electromagnetic coupling, Near Field Communication (NFC), Radio Frequency (RF) communication, Bluetooth, Wi-Fi, or other proprietary or non-proprietary wireless communication schemes. Communication antenna 840 may telemeter data at a high frequency, such as around 2.4 gigahertz (GHz). IMD 814 may receive messages from external computing device 20, another medical device worn, or implanted in, patient 12 or some other source, which may cause IMD 814 to take a measurement via the electrodes, or other sensors, or to deliver electrical stimulation therapy. In some examples, IMD 814 may output the measured state of charge or depth of discharge of power source 832 based on the measurements from Coulomb counter 850.

In some examples, external computing device 822 may include a user interface comprising a display and audio output. External computing device 822 may receive a message from communication circuitry 838, controlled by processing circuitry 834, that causes external computing device 822 to display state of charge information for power source 832 to a user, such as a patient or a caregiver. In some examples, external computing device 822 may provide an alert, e.g., a visual and/or audio alert, when the state of charge reaches a threshold or when an estimated longevity for power source 832, based on the state of charge, reaches a threshold.

In some examples, memory 836 includes computer-readable instructions that, when executed by processing circuitry 834, cause IMD 814 and processing circuitry 834 to perform various functions attributed to IMD 814 and processing circuitry 834 herein. Memory 836 may include any volatile, non-volatile, magnetic, optical, or electrical media, such as a random-access memory (RAM), read-only memory (ROM), non-volatile RAM (NVRAM), electrically erasable programmable ROM (EEPROM), flash memory, or any other digital media. Memory 836 may store, as examples, programmed values for one or more operational parameters of IMD 814 and/or data collected by IMD 814, e.g., posture, heart rate, activity level, respiration rate, therapy delivery statistics, and other parameters, as well as digitized versions of physiological signals sensed by IMD 814, for transmission to another device using communication circuitry 838.

In the example of FIG. 8. IMD 814 includes a rechargeable power source 832 that may be coupled to the electronic circuitry provided in IMD 814 and is configured to provide electrical power to these circuits outside of a charging session, e.g., when not receiving wireless power from a primary coil. Power source 832 may be an electrical energy storage device that is inductively rechargeable by imposing one or more magnetic fields onto IMD 814, wherein energy from these imposed field(s) may induce an electrical energy into receive coil 816 and, thereby, to recharging circuitry 830. In other examples, power source 832 may be a primary, e.g., non-rechargeable battery. Coulomb counter 850 may measure the amount of current to the circuitry of IMD 14, as described above in relation to FIGS. 1 and 2. In the example of a rechargeable power source, Coulomb counter 850 may also measure the amount of power delivered to power source 832 from recharging circuitry 830.

As shown in FIG. 2, device recharging circuitry 830 is coupled to power source 832 and may receive electrical energy induced in receive coil 816 by one or more electromagnetic fields imposed on the coil during a charging session, and to regulate the energy to provide a level of energy that is provided to power source 832 for the purpose of recharging power source 832 and/or powering the other circuitry included as part of IMD 814. Device recharging circuitry 830 may perform various energy conditioning functions to the energy inductively generated in receive coil 816 during the charging session by the primary coil, e.g., primary coil 20 described above in relation to FIG. 1. For example, recharging circuitry 830 may provide rectification, voltage level regulation, current level regulation, and/or other signal processing functions to generate the “recharging energy” provided to charge power source 832.

In the illustrated example, IMD 814 includes processing circuitry 834 and an associated memory 836, sensing circuitry 842, one or more sensors 844, and the communication circuitry 838 coupled to antenna 840 as described above. However, IMD 814 need not include all of these components, or may include additional components.

Processing circuitry 834 may be configured to provide information including a state of charge, and/or temperature information related to a battery, e.g., a battery located in IMD 814, determining a level of inductive coupling, e.g., energy level being generated in a receive coil located in IMD 814 as a result of an electromagnetic field or fields being imposed on IMD 814, and generate information related to this inductively received energy for transmission by the communication antenna or separate antenna and associated power conditioning circuitry of IMD 814.

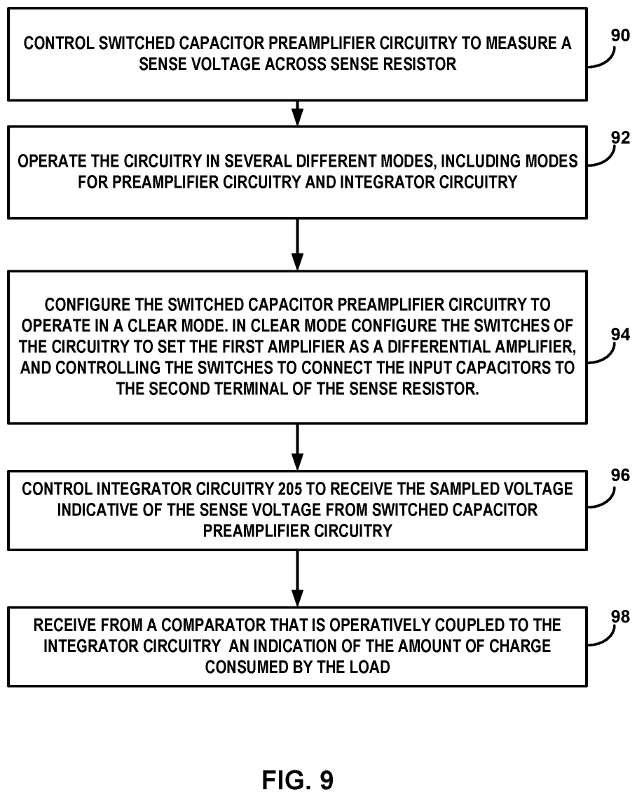

FIG. 9 is a flow diagram illustrating an example operation of the charge sense circuitry of this disclosure. The blocks of FIG. 9 describe one example technique for measuring an amount of electrical energy consumed over a duration of time, such as for a battery powered device. FIGS. 2-3C may be used to explain the blocks of FIG. 9.

Digital control circuitry 125 may control switched capacitor preamplifier circuitry 203 of VCO block 211 to measure a sense voltage across sense resistor 214 (90). Digital control circuitry 125 may operate VCO block 211 in several different modes, including modes for preamplifier circuitry 203 and integrator circuitry 205 (92).

Digital control circuitry 125 may configure switched capacitor preamplifier circuitry 203 to operate in a clear mode. As described above in relation to FIGS. 2, 3B and 3C, for the clear mode digital control circuitry 125 may set up a first amplifier, e.g., PRE1 250 as a differential amplifier. Also for clear mode, control switches, such as switches of switch matrix 222, to connect input capacitors Cadj1 234 and Cadj2 236 to BPLUS 206, connected to the second terminal of sense resistor, RSense 214 (94).

Digital control circuitry 125 may also control integrator circuitry 205 to receive the sampled voltage indicative of the sense voltage from switched capacitor preamplifier circuitry 203 (96). In other words, at the end of the clear mode, for PRE2 252, INT2 288 may receive the sampled voltage, operate in an integrate mode to integrate the sampled voltage, then output the integrated sampled voltage to comparator 296. As described above in relation to FIGS. 4A and 4B, INT2 288 may count down (or count up in some examples) until crossing the threshold for comparator 296, which may generate a count indicating a fixed amount of charge pulled from the electrical energy storage device during that period, e.g., from battery 202 of FIG. 2.

Finally, digital control circuitry 125 may receive from e.g., comparator 296, which is operatively coupled to integrator circuitry 205, an indication of the amount of charge consumed by load 212 (98).

The techniques of this disclosure may also be described in the following examples.

Example 1: A circuit configured to measure an amount of charge consumed over a duration of time comprising a sense resistor comprising a first terminal and a second terminal, wherein the first terminal connects to a power supply terminal and the second terminal connects to a load, and wherein the sense resistor is configured to develop a sense voltage proportional to an instantaneous load current, wherein the instantaneous load current is a magnitude of current consumed by the load; switched capacitor preamplifier circuitry comprising an amplifier, input switches, and input capacitors, wherein the switched capacitor preamplifier circuitry is configured to operate in a plurality of modes comprising a clear mode, wherein when operating in the clear mode, the amplifier is configured as a differential amplifier and the input switches connect the input capacitors to the second terminal of the sense resistor; integrator circuitry configured to receive a sampled voltage indicative of the sense voltage from the switched capacitor preamplifier circuitry and, while in an integrate mode, integrate the sampled voltage and output the integrated sampled voltage; and a comparator configured to: receive the integrated sampled voltage from the integrator circuitry; and compare the received integrated sampled voltage to a threshold voltage; output an indication of the amount of charge consumed by the load, based on the comparison.

Example 2: The circuit of example 1, wherein the clear mode is a first clear mode, wherein the plurality of modes for the switched capacitor preamplifier circuitry further comprise: a second clear mode, wherein when operating in the second clear mode, the amplifier is configured as a unity gain amplifier connected to a reference voltage; a gain mode, wherein when operating in the gain mode, the amplifier is configured as a differential amplifier and the input switches connect the input capacitors across the sense resistor, and wherein a timing order for the plurality of modes is: the second clear mode, the first clear mode, the gain mode.

Example 3: The circuit of any of examples 1 and 2, wherein: the switched capacitor preamplifier circuitry comprises a dual path arrangement including a first path and a second path, the integrator circuitry comprises the dual path arrangement including the first path and the second path, the first path operates with a first clock phase, and the second path operates with a second clock phase opposite to the first clock phase, such that the first path and the second path implement bilinear sampling of the sense voltage.

Example 4: The circuit of any of examples 1 through 3, wherein the switched capacitor preamplifier circuitry is configured with a programmable gain.

Example 5: The circuit of any of examples 1 through 4, further a chop multiplexor connected between the sense resistor and the switched capacitor preamplifier circuitry, wherein: the chop multiplexor comprises a plurality of switches; the chop multiplexor is configured to connect to the sense resistor in a first polarity for a first duration; and the chop multiplexor is configured to connect to the sense resistor in a second polarity opposite to the first polarity for a second duration.

Example 6: The circuit of example 5, wherein: for first polarity, the switched capacitor preamplifier circuitry is configured to sample the sense voltage with a positive gain, and for second polarity, the switched capacitor preamplifier circuitry is configured to sample the sense voltage with an inverted gain.

Example 7: The circuit of any of examples 5 and 6, wherein the first duration is the same as the second duration.

Example 8: The circuit of any of examples 5 through 7, wherein the first duration is at least 100 times a sampling period of the switched capacitor preamplifier circuitry.

Example 9: The circuit of any of examples 5 through 8, further comprising an anti-aliasing filter, the anti-aliasing filter comprising filter input terminals and filter output terminals, wherein the filter input terminals connect across the sense resistor, and the filter output terminals connect to the chop multiplexor.

Example 10: The circuit of any of examples 1 through 9, wherein: the amplifier is a first amplifier, the integrator circuitry comprises an integration amplifier and a precharge capacitor; the integrator circuitry is configured to operate in a plurality of modes including an integrate mode and a reset mode, the integrate mode operates during the first clear mode and the second clear mode for the switched capacitor preamplifier circuitry, and during the reset mode, the integrator circuitry is configured to charge the precharge capacitor to an output voltage of the integration amplifier.

Example 11: The circuit of any of examples 8 through 10, further comprising a charge dump circuit configured to apply a fixed amount of charge to the integration amplifier after the comparator outputs the indication of the fixed amount of charge consumed by the load.

Example 12: A system comprising a circuit configured to measure an amount of charge consumed over a duration of time, the circuit comprising: a sense resistor comprising a first terminal and second terminal, wherein the first terminal connects to a power supply terminal and the second terminal connects to a load, and wherein the sense resistor is configured to develop a sense voltage proportional to an instantaneous load current and the instantaneous load current is a magnitude of current consumed by the load; switched capacitor preamplifier circuitry comprising an amplifier, input switches, and input capacitors, the switched capacitor preamplifier circuitry configured to operate in a plurality of modes comprising a clear mode, wherein when operating in the clear mode, the amplifier is configured as a differential amplifier and the input switches connect the input capacitors to the second terminal of the sense resistor; integrator circuitry configured to receive the sampled voltage indicative of the sense voltage from the switched capacitor preamplifier circuitry, and while in integrate mode, integrate the sampled voltage and output the integrated sampled voltage; a comparator configured to: receive the integrated sampled voltage from the integrator circuitry; and compare the received integrated sampled voltage to a threshold voltage; output an indication of a fixed amount of charge consumed by the load, based on the comparison; and digital control circuitry configured to output control signals and control operation of the switched capacitor preamplifier circuitry, the integrator circuitry and input switches by means of the control signals.

Example 13: The system of example 12, where the digital control circuitry comprises processing circuitry.

Example 14: The system of any of examples 12 and 13, wherein: the switched capacitor preamplifier circuitry is configured with programmable gain, and the digital control circuitry is further configured to control the programmable gain by means of the control signals.

Example 15: The system of any of examples 12 through 14, further comprising a chop multiplexor connected between the sense resistor and the switched capacitor preamplifier circuitry, wherein: the chop multiplexor comprises a plurality of switches; the chop multiplexor is configured to connect to the sense resistor in a first polarity for a first duration; and the chop multiplexor is configured to connect to the sense resistor in a second polarity opposite to the first polarity for a second duration the digital control circuitry is further configured to control operation of the plurality of switches of the chop multiplexor.

Example 16: The system of any of examples 12 through 15, wherein: the amplifier is a first amplifier; the integrator circuitry comprises an integration amplifier and a precharge capacitor; the integrator circuitry is configured to operate in a plurality of modes based on the control signals from the digital control circuitry, wherein the plurality of modes includes an integrate mode and a reset mode, the integrate mode operates during the first clear mode and the second clear mode for the switched capacitor preamplifier circuitry, during the reset mode, the integrator circuitry is configured to charge the precharge capacitor to an output voltage of the integration amplifier.

Example 17: The system of any of examples 12 through 16, wherein the digital control circuitry is configured to: receive, from the comparator, the indication of the fixed amount of charge consumed by the load; and output an electrical signal comprising a count amount of charge consumed by the load.

Example 18: A method for measuring an amount of electrical energy consumed over a duration of time comprising controlling, by digital control circuitry, a switched capacitor switched capacitor preamplifier circuit to measure a sense voltage across a sense resistor, wherein the sense voltage is proportional to an instantaneous load current, wherein the switched capacitor preamplifier circuit samples the sense voltage and outputs the sampled sense voltage, wherein the instantaneous load current is a magnitude of current consumed by a load, wherein the sense resistor comprises a first terminal and second terminal, wherein the first terminal connects to a power supply terminal, wherein the second terminal connects to a load, and wherein the switched capacitor preamplifier circuit comprises: a first amplifier, switches, input capacitors, and wherein controlling the switched capacitor preamplifier circuit comprises operating, by the digital control circuitry, the switched capacitor preamplifier circuit in a plurality of modes; configuring, by the digital control circuitry, the switched capacitor preamplifier circuit to operate in a clear mode, wherein the clear mode comprises: configuring, by the digital control circuitry, the first amplifier as a differential amplifier, and controlling the switches to connect the input capacitors to the second terminal of the sense resistor; controlling, by the digital control circuitry, an integrator circuit to: receive the sampled voltage indicative of the sense voltage from the switched capacitor preamplifier circuit; operate in an integrate mode to integrate the sampled voltage, and output the integrated sampled voltage; receiving, by the digital control circuitry and from a comparator operatively coupled to the integrator circuit, an indication of the amount of charge consumed by the load.

Example 19: The method of example 18, wherein the clear mode is a first clear mode, the method further comprising operating, by the digital control circuitry, the switched capacitor preamplifier circuit in a second clear mode, wherein the digital control circuitry operates the switches such that the first amplifier is configured as a unity gain amplifier connected to a reference voltage; operating, by the digital control circuitry, the switched capacitor preamplifier circuit in a gain mode, wherein the first amplifier is configured as a differential amplifier, and wherein the input switches connect the input capacitors across the sense resistor.

Example 20: The method of any of examples 18 and 19, further comprising controlling, by the digital control circuitry, a chop multiplexor connected between the sense resistor and the switched capacitor preamplifier circuit, wherein the chop multiplexor comprises a plurality of switches; wherein controlling the chop multiplexor comprises operating the plurality of switches of the chop multiplexor: to connect to the sense resistor in a first polarity for a first duration, wherein for first polarity, the switched capacitor preamplifier circuit is configured to sample the sense voltage with a positive gain, and to connect to the sense resistor in a second polarity opposite to the first polarity for a second duration, wherein for second polarity, the switched capacitor preamplifier circuit is configured to sample the sense voltage with an inverted gain.

In one or more examples, the functions described above may be implemented in hardware, software, firmware, or any combination thereof. For example, the various components of FIGS. 1, 3A and 3B for example, such as digital circuitry 125, may be implemented in hardware, software, firmware, or any combination thereof. If implemented in software, the functions may be stored on or transmitted over, as one or more instructions or code, a computer-readable medium and executed by a hardware-based processing unit. Computer-readable media may include computer-readable storage media, which corresponds to a tangible medium such as data storage media, or communication media including any medium that facilitates transfer of a computer program from one place to another, e.g., according to a communication protocol. In this manner, computer-readable media generally may correspond to (1) tangible computer-readable storage media which is non-transitory or (2) a communication medium such as a signal or carrier wave. Data storage media may be any available media that can be accessed by one or more computers or one or more processors to retrieve instructions, code and/or data structures for implementation of the techniques described in this disclosure. A computer program product may include a computer-readable medium.

The term “non-transitory” may indicate that the storage medium is not embodied in a carrier wave or a propagated signal. In certain examples, a non-transitory storage medium may store data that can, over time, change (e.g., in RAM or cache). By way of example, and not limitation, such computer-readable storage media, may include random access memory (RAM), read only memory (ROM), programmable read only memory (PROM), erasable programmable read only memory (EPROM), electronically erasable programmable read only memory (EEPROM), flash memory, a hard disk, a compact disc ROM (CD-ROM), a floppy disk, a cassette, magnetic media, optical media, or other computer readable media. In some examples, an article of manufacture may include one or more computer-readable storage media.

Also, any connection is properly termed a computer-readable medium. For example, if instructions are transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. It should be understood, however, that computer-readable storage media and data storage media do not include connections, carrier waves, signals, or other transient media, but are instead directed to non-transient, tangible storage media. Combinations of the above are also included within the scope of computer-readable media.

Instructions may be executed by one or more processors, such as one or more DSPs, general purpose microprocessors, ASICs, FPGAs, or other equivalent integrated or discrete logic circuitry. Accordingly, the term “processor” and “processing circuitry,” as used herein may refer to any of the foregoing structure or any other structure suitable for implementation of the techniques described herein. Also, the techniques could be fully implemented in one or more circuits or logic elements.

The techniques of this disclosure may be implemented in a wide variety of devices or apparatuses, including, an IC or a set of ICs (e.g., a chip set). Various components, modules, or units are described in this disclosure to emphasize functional aspects of devices configured to perform the disclosed techniques, but do not necessarily require realization by different hardware units. Rather, as described above, various units may be combined in a hardware unit or provided by a collection of interoperative hardware units, including one or more processors as described above, in conjunction with suitable software and/or firmware.

Various examples of the disclosure have been described. These and other examples are within the scope of the following claims.

1: A circuit configured to measure an amount of charge consumed over a duration of time, the circuit comprising:
a sense resistor comprising a first terminal and a second terminal, wherein the first terminal connects to a power supply terminal and the second terminal connects to a load, and wherein the sense resistor is configured to develop a sense voltage proportional to an instantaneous load current, wherein the instantaneous load current is a magnitude of current consumed by the load;
switched capacitor preamplifier circuitry comprising an amplifier, input switches, and input capacitors, wherein the switched capacitor preamplifier circuitry is configured to operate in a plurality of modes comprising a clear mode, wherein when operating in the clear mode, the amplifier is configured as a differential amplifier and the input switches connect the input capacitors to the second terminal of the sense resistor;
integrator circuitry configured to receive a sampled voltage indicative of the sense voltage from the switched capacitor preamplifier circuitry and, while in an integrate mode, integrate the sampled voltage, and output an integrated sampled voltage; and
a comparator configured to:
receive the integrated sampled voltage from the integrator circuitry;
compare the received integrated sampled voltage to a threshold voltage; and
output an indication of an amount of charge consumed by the load, based on the comparison.

2: The circuit of claim 1,
wherein the clear mode is a first clear mode,
wherein the plurality of modes for the switched capacitor preamplifier circuitry further comprises:
a second clear mode, wherein when operating in the second clear mode, the amplifier is configured as a unity gain amplifier connected to a reference voltage;
a gain mode, wherein when operating in the gain mode, the amplifier is configured as a differential amplifier and the input switches connect the input capacitors across the sense resistor, and
wherein a timing order for the plurality of modes is: the second clear mode, the first clear mode, the gain mode.

3: The circuit of claim 1, wherein:
the switched capacitor preamplifier circuitry comprises a dual path arrangement including a first path and a second path,
the integrator circuitry comprises the dual path arrangement including the first path and the second path,
the first path operates with a first clock phase, and
the second path operates with a second clock phase opposite to the first clock phase, such that the first path and the second path implement bilinear sampling of the sense voltage.

4: The circuit of claim 1, wherein the switched capacitor preamplifier circuitry is configured with a programmable gain.

5: The circuit of claim 1, further comprising a chop multiplexor connected between the sense resistor and the switched capacitor preamplifier circuitry, wherein:
the chop multiplexor comprises a plurality of switches;
the chop multiplexor is configured to connect to the sense resistor in a first polarity for a first duration; and
the chop multiplexor is configured to connect to the sense resistor in a second polarity opposite to the first polarity for a second duration.

6: The circuit of claim 5, wherein:
for first polarity, the switched capacitor preamplifier circuitry is configured to sample the sense voltage with a positive gain, and
for second polarity, the switched capacitor preamplifier circuitry is configured to sample the sense voltage with an inverted gain.

7: The circuit of claim 5, wherein the first duration is the same as the second duration.

8: The circuit of claim 5, wherein the first duration is at least 100,000 times a sampling period of the switched capacitor preamplifier circuitry.

9: The circuit of claim 5, further comprising an anti-aliasing filter, the anti-aliasing filter comprising filter input terminals and filter output terminals, wherein:
the filter input terminals connect across the sense resistor, and
the filter output terminals connect to the chop multiplexor.

10: The circuit of claim 1, wherein:
the amplifier is a first amplifier,
the integrator circuitry comprises an integration amplifier and a precharge capacitor;
the integrator circuitry is configured to operate in a plurality of modes including an integrate mode and a reset mode,
the integrate mode operates during the first clear mode and the second clear mode for the switched capacitor preamplifier circuitry, and
during the reset mode, the integrator circuitry is configured to charge the precharge capacitor to an output voltage of the integration amplifier.

11: The circuit of claim 1, further comprising a charge dump circuit configured to apply a fixed amount of charge to the integration amplifier after the comparator outputs the indication of the fixed amount of charge consumed by the load.

12: A system comprising:
a circuit configured to measure an amount of charge consumed over a duration of time, the circuit comprising:
a sense resistor comprising a first terminal and a second terminal, wherein the first terminal connects to a power supply terminal and the second terminal connects to a load, and wherein the sense resistor is configured to develop a sense voltage proportional to an instantaneous load current, wherein the instantaneous load current is a magnitude of current consumed by the load;
switched capacitor preamplifier circuitry comprising an amplifier, input switches, and input capacitors, wherein the switched capacitor preamplifier circuitry is configured to operate in a plurality of modes comprising a clear mode, wherein when operating in the clear mode, the amplifier is configured as a differential amplifier and the input switches connect the input capacitors to the second terminal of the sense resistor;
integrator circuitry configured to receive a sampled voltage indicative of the sense voltage from the switched capacitor preamplifier circuitry and, while in an integrate mode, integrate the sampled voltage, and output an integrated sampled voltage; and
a comparator configured to:
receive the integrated sampled voltage from the integrator circuitry;
compare the received integrated sampled voltage to a threshold voltage; and
output an indication of an amount of charge consumed by the load, based on the comparison; and
digital control circuitry configured to output control signals and control operation of the switched capacitor preamplifier circuitry, the integrator circuitry and input switches by means of the control signals.

13: The system of claim 12, wherein the digital control circuitry is configured to:
receive, from the comparator, the indication of the fixed amount of charge consumed by the load; and
output an electrical signal comprising a count of the amount of charge consumed by the load.

14: The system of claim 12, further comprising an implantable medical device,
wherein processing circuitry for the implantable medical device is configured to receive the electrical signal from the digital control circuitry,
wherein the processing circuitry is configured to control communication circuitry of the implantable medical device to output an electronic message comprising one or more of:
the amount of charge consumed by the load, wherein the load comprises one or more functional blocks of the implantable medical device,
an estimated longevity for the implantable medical device; or
a state of charge of an electrical energy storage device of the implantable medical device,
wherein the electronic message is configured to be received by an external computing device.

15: The system of claim 14, wherein the external computing device is configured to inform a user to recharge the electrical energy storage device of the implantable medical device based on the amount of charge consumed by the load, output a message to a user with an estimated longevity of the implantable medical device, based on the amount of charge consumed by the load, or both.

16: The system of claim 12, further comprising a chop multiplexor connected between the sense resistor and the switched capacitor preamplifier circuitry, wherein:
the chop multiplexor comprises a plurality of switches;
the chop multiplexor is configured to connect to the sense resistor in a first polarity for a first duration; and
the chop multiplexor is configured to connect to the sense resistor in a second polarity opposite to the first polarity for a second duration the digital control circuitry is further configured to control operation of the plurality of switches of the chop multiplexor.

17: The system of claim 12, wherein:
the amplifier is a first amplifier;
the integrator circuitry comprises an integration amplifier and a precharge capacitor; and
the integrator circuitry is configured to operate in a plurality of modes based on the control signals from the digital control circuitry, wherein the plurality of modes includes an integrate mode and a reset mode, the integrate mode operates during the first clear mode and the second clear mode for the switched capacitor preamplifier circuitry, and during the reset mode, the integrator circuitry is configured to charge the precharge capacitor to an output voltage of the integration amplifier.

18: A method for measuring an amount of electrical energy consumed over a duration of time, the method comprising:
controlling, by digital control circuitry, a switched capacitor preamplifier circuit to measure a sense voltage across a sense resistor, wherein the sense voltage is proportional to an instantaneous load current, wherein the switched capacitor preamplifier circuit samples the sense voltage and outputs the sampled sense voltage, wherein the instantaneous load current is a magnitude of current consumed by a load, wherein the sense resistor comprises a first terminal and second terminal, wherein the first terminal connects to a power supply terminal, wherein the second terminal connects to a load, and wherein the switched capacitor preamplifier circuit comprises a first amplifier, switches, and input capacitors, and wherein controlling the switched capacitor preamplifier circuit comprises operating, by the digital control circuitry, the switched capacitor preamplifier circuit in a plurality of modes;
configuring, by the digital control circuitry, the switched capacitor preamplifier circuit to operate in a clear mode, wherein the clear mode comprises:
configuring, by the digital control circuitry, the first amplifier as a differential amplifier; and
controlling the switches to connect the input capacitors to the second terminal of the sense resistor;
controlling, by the digital control circuitry, an integrator circuit to:
receive the sampled voltage indicative of the sense voltage from the switched capacitor preamplifier circuit;
operate in an integrate mode to integrate the sampled voltage; and
output an integrated sampled voltage; and
receiving, by the digital control circuitry and from a comparator operatively coupled to the integrator circuit, an indication of an amount of charge consumed by the load.

19: The method of claim 18, wherein the clear mode is a first clear mode, the method further comprising:
operating, by the digital control circuitry, the switched capacitor preamplifier circuit in a second clear mode, wherein the digital control circuitry operates the switches such that the first amplifier is configured as a unity gain amplifier connected to a reference voltage; and
operating, by the digital control circuitry, the switched capacitor preamplifier circuit in a gain mode, wherein the first amplifier is configured as a differential amplifier, and wherein the input switches connect the input capacitors across the sense resistor.

20: The method of claim 18, further comprising:
controlling, by the digital control circuitry, a chop multiplexor connected between the sense resistor and the switched capacitor preamplifier circuit, wherein the chop multiplexor comprises a plurality of switches,
wherein controlling the chop multiplexor comprises operating the plurality of switches of the chop multiplexor:
to connect to the sense resistor in a first polarity for a first duration, wherein for first polarity, the switched capacitor preamplifier circuit is configured to sample the sense voltage with a positive gain; and
to connect to the sense resistor in a second polarity opposite to the first polarity for a second duration, wherein for second polarity, the switched capacitor preamplifier circuit is configured to sample the sense voltage with an inverted gain.
